(19) United States
(12) Patent Application Publication
(10) Pub. No.: US 2025/0380382 A1
(43) Pub. Date: Dec. 11, 2025

(54) LIQUID-COOLING DYNAMIC FLOW CONTROL METHOD AND LIQUID-COOLING SYSTEM

(71) Applicants: INVENTEC (PUDONG) TECHNOLOGY CORPORATION, Shanghai (CN); INVENTEC CORPORATION, Taipei City (TW)

(72) Inventors: Chien-Ming LEE, Taipei City (TW); Kai-Yang TUNG, Taipei City (TW)

(73) Assignees: INVENTEC (PUDONG) TECHNOLOGY CORPORATION, Shanghai (CN); INVENTEC CORPORATION, Taipei City (TW)

(21) Appl. No.: 18/976,037

(22) Filed: Dec. 10, 2024

(30) Foreign Application Priority Data
Jun. 11, 2024 (CN) 202410749635.5

(51) Int. Cl. H05K 7/20

(52) U.S. Cl. CPC H05K 7/20281; H05K 7/20254; H05K 7/20272; H05K 7/20772

(57) ABSTRACT

A liquid-cooling dynamic flow control method includes performing by a control device: obtaining at least one temperature difference between a set temperature and at least one current operating temperature of at least one power component; obtaining a set of target control parameters corresponding to the at least one temperature difference according to a pre-stored parameter table, wherein the pre-stored parameter table records the correspondence between a plurality of preset temperature intervals and a plurality of sets of preset control parameters, and each of the plurality of sets of preset control parameters includes a proportional coefficient, an integral coefficient and a differential coefficient; using the target control parameter and the at least one temperature difference to obtain a heat dissipation control parameter; and adjusting a rotational speed of a liquid-cooling pump with the heat dissipation control parameter.

### CROSS-REFERENCE TO RELATED APPLICATIONS

This non-provisional application claims priority under 35 U.S.C. § 119 (a) on Patent Application No(s). 202410749635.5 filed in China on Jun. 11, 2024, the entire contents of which are hereby incorporated by reference.

### BACKGROUND

### 1. Technical Field

This disclosure relates to a liquid-cooling dynamic flow control method and liquid-cooling system.

### 2. Related Art

Currently, effective dynamic control method for the flow of the liquid-cooling rack server is not well-established. The main reasons result from the design of the cooling distribution unit (CDU) and the issue of the time delay in server data access on the rack server. The design of the cooling distribution unit is mainly to monitor its outlet water temperature (or return water temperature) and then provide the corresponding required flow rate for liquid-cooling pump control. This requires conducting experimental measurements to obtain relevant data, using the data to obtain the required flow rate based on the coolant temperature, and then controlling the liquid-cooling pump at the required flow rate.

In the above method, the coolant temperature-flow rate relation needs to be re-adjusted on a case-by-case basis for different coolant distribution control units and different rack server densities, which causes engineers spending too much time adjusting the lookup tables for liquid-cooling pump control. Usually, liquid-cooling pumps are mostly operated in a fully operating state (100%) which is not necessary for most power component, resulting in unnecessary energy consumption. In addition, retrieving data from all the rack servers, such as temperature, power, etc., are required for the dynamical control of the liquid-cooling pump. For the rack server, the number of servers can reach 10 to 20 (or even more), and the time delay problem in data acquisition caused by the large amount of data and the long acquisition makes dynamic control more difficult.

### SUMMARY

Accordingly, this disclosure provides a liquid-cooling dynamic flow control method and liquid-cooling system.

According to one or more embodiment of this disclosure, a liquid-cooling dynamic flow control method comprises performing by a control device: obtaining at least one temperature difference between a set temperature and at least one current operating temperature of at least one power component; obtaining a set of target control parameters corresponding to the at least one temperature difference according to a pre-stored parameter table, wherein the pre-stored parameter table records correspondence between a plurality of preset temperature intervals and a plurality sets of preset control parameters, and each of the plurality sets of preset control parameters comprises a proportional coefficient, an integral coefficient and a differential coefficient; obtaining a heat dissipation control parameter using the set of target control parameters and the at least one temperature difference; and using the heat dissipation control parameter to adjust rotational speed of a liquid-cooling pump.

According to one or more embodiment of this disclosure, a liquid-cooling system which is applicable for dissipating heat from at least one power component, comprises a liquid-cooling pump, at least one liquid-cooling plate, at least one temperature sensor and a control device. The liquid-cooling pump is configured to set rotational speed according to a heat dissipation control parameter to output coolant. The at least one liquid-cooling plate is in thermal contact with the at least one power component and connected to the liquid-cooling pump. The at least one temperature sensor is disposed to correspond to the at least one power component, and configured to obtain at least one current operating temperature of the at least one power component. The control device is connected to the liquid-cooling pump and the at least one temperature sensor, and is configured to obtain a set of target control parameters corresponding to at least one temperature difference according to a pre-stored parameter table, obtain a heat dissipation control parameter using the set of target control parameters and the at least one temperature difference, and use the heat dissipation control parameter to adjust rotational speed of the liquid-cooling pump, wherein the pre-stored parameter table records correspondence between a plurality of preset temperature intervals and a plurality sets of preset control parameters, and each of the plurality sets of preset control parameters comprises a proportional coefficient, an integral coefficient and a differential coefficient.

In view of the above description, the liquid-cooling dynamic flow control method and liquid-cooling system of the present disclosure, according to a pre-stored parameter table that records the correspondence a plurality of preset temperature intervals and a plurality sets of preset control parameters, may select the corresponding target control parameters according to which preset temperature interval the current operating temperature of the power component belongs to, thereby dynamically adjusting the rotational speed of a liquid-cooling pump. In this way, the liquid-cooling pump may be prevented from operating in a fully operating state for a long time, and for rack server containing several to dozens of servers, the above dynamic control method may solve the time delay problem in data acquisition caused by the large amount of data and the long acquisition time.

### BRIEF DESCRIPTION OF THE DRAWINGS

The present disclosure will become more fully understood from the detailed description given hereinbelow and the accompanying drawings which are given by way of illustration only and thus are not limitative of the present disclosure and wherein:

FIG. 1 is a block diagram of a liquid-cooling system according to an embodiment of the present disclosure;

FIG. 2 is a flow chart of a liquid-cooling dynamic flow control method according to an embodiment of the present disclosure;

FIG. 3 shows the relationship between the set temperature, reaction temperature and multiple preset temperature intervals recorded in the pre-stored parameter table in the liquid-cooling dynamic flow control method according to an embodiment of the present disclosure;

FIG. 4 schematically shows the temperature change curve of a power component for heat dissipation using a liquid-cooling dynamic flow control method according to an embodiment of the present disclosure;

FIG. 5 is a schematic diagram illustrating the relationship between the temperature change of the power component and the rotational speed of the liquid-cooling pump according to an embodiment of the present disclosure; and

FIG. 6 is another schematic diagram illustrating the relationship between the temperature change of the power component and the rotational speed of the liquid-cooling pump according to an embodiment of the present disclosure.

### DETAILED DESCRIPTION

In the following detailed description, for purposes of explanation, numerous specific details are set forth in order to provide a thorough understanding of the disclosed embodiments. According to the description, claims and the drawings disclosed in the specification, one skilled in the art may easily understand the concepts and features of the present invention. The following embodiments further illustrate various aspects of the present invention, but are not meant to limit the scope of the present invention.

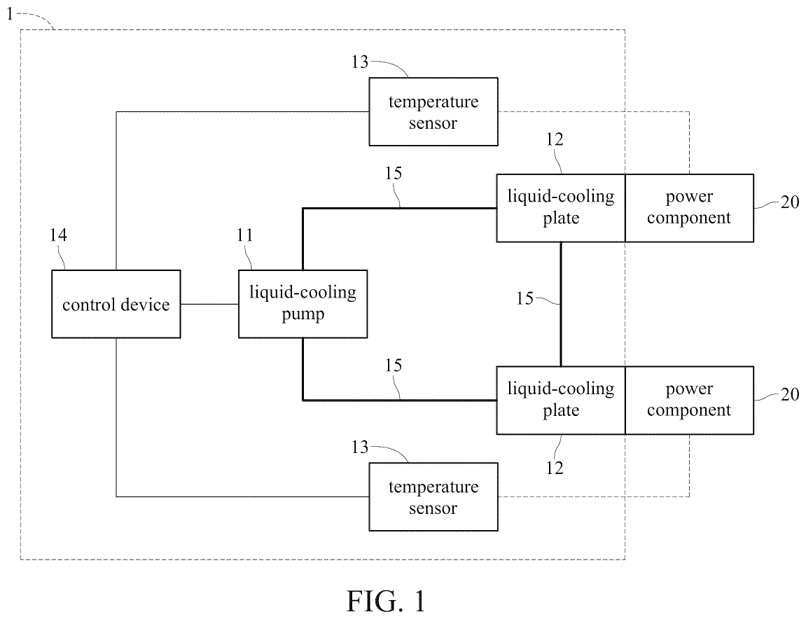

Please refer to FIG. 1 which is a block diagram of a liquid-cooling system according to an embodiment of the present disclosure. As shown in FIG. 1, the liquid-cooling system 1 which is applicable for dissipating heat from at least one power component 20, comprises a liquid-cooling pump 11, at least one liquid-cooling plate 12, at least one temperature sensor 13 and a control device 14. The liquid-cooling pump 11 is configured to set rotational speed according to a heat dissipation control parameter to output coolant. The at least one liquid-cooling plate 12 is in thermal contact with the at least one power component 20 and connected to the liquid-cooling pump 11. The at least one temperature sensor 13 is disposed to correspond to the at least one power component 20, and configured to obtain at least one current operating temperature of the at least one power component 20.

The control device 14 is connected to the liquid-cooling pump 11 and the at least one temperature sensor 13, and is configured to obtain a set of target control parameters corresponding to at least one temperature difference according to a pre-stored parameter table, obtain a heat dissipation control parameter using the set of target control parameters and the at least one temperature difference, and use the heat dissipation control parameter to adjust rotational speed of a liquid-cooling pump 11, wherein the pre-stored parameter table records correspondence between a plurality of preset temperature intervals and a plurality sets of preset control parameters, and each of the plurality sets of preset control parameters comprises a proportional coefficient, an integral coefficient and a differential coefficient.

The liquid-cooling system in this disclosure is used to dissipate heat for at least one power component, and may especially be used to dissipate heat for a plurality of power components in a large rack server. The power component 20 may be, for example, a computing unit of a server, such as a central processing unit (CPU), a graphics processing unit (GPU), etc. In the embodiment of FIG. 1, the number of power components 20 is two, but is not limited thereto. Furthermore, the number of liquid-cooling plates 12 used to dissipate heat from the power components 20 is not limited to be two as shown in FIG. 1, and the number of temperature sensors 13 used to measure the current operating temperature of the power component 20 is not limited to be two shown in FIG. 1.

In this embodiment, the liquid-cooling pump 11 is connected to the liquid-cooling plate 12 through the liquid-cooling pipeline 15 and is configured to set the rotational speed according to a heat dissipation control parameter to output coolant. FIG. 1 exemplarily shows that the liquid-cooling pump 11 and the two liquid-cooling plates 12 are connected in series through the liquid-cooling pipeline 15, but the present disclosure is not limited thereto. For example, the two liquid-cooling plates 12 may also be connected to the liquid-cooling pump 11 in parallel. The liquid-cooling plate 12 is in thermal contact with the power component 20 to dissipate heat through the liquid-cooling circuit formed by the liquid cooling pump 11, the liquid-cooling plate 12 and the liquid-cooling pipeline 15. The temperature sensor 13 may be a temperature sensor provided on the server motherboard corresponding to the power component 20, and is configured to provide temperature information of each power component 20 to the control device 14.

The control device 14 may include one or more processing/control units with data receiving, recording, computing, storage and output functions. The processing/control unit is, for example, a microcontroller, a central processing unit, a graphics processor, a programmable logic controller, or any combination of the above. In particular, the control device 14 may be a coolant distribution control unit (CDU), and configured to control the rotational speed of the liquid-cooling pump according to the temperature information of the power component provided by the temperature sensor 13, so as to control the flow rate of the coolant to achieve good heat dissipation effect, while preventing the liquid-cooling pump 11 from being in an over-operation state.

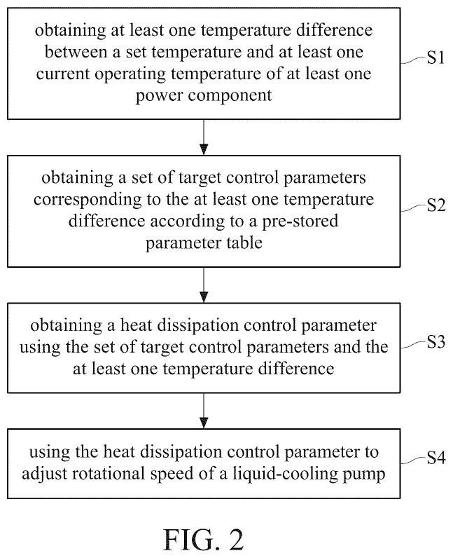

Please refer to FIG. 2 along with FIG. 1, FIG. 2 is a flow chart of a liquid-cooling dynamic flow control method according to an embodiment of the present disclosure. As shown in FIG. 2, the liquid-cooling dynamic flow control method comprises performing by a control device: step S1: obtaining at least one temperature difference between a set temperature and at least one current operating temperature of at least one power component; step S2: obtaining a set of target control parameters corresponding to the at least one temperature difference according to a pre-stored parameter table; step S3: obtaining a heat dissipation control parameter using the set of target control parameters and the at least one temperature difference; and step S4: using the heat dissipation control parameter to adjust rotational speed of a liquid-cooling pump.

In step S1, the control device 14 may firstly obtain the target temperature of the power component to be the set temperature for preparation, and obtain the current operating temperature of the power component 20 through the temperature sensor 13, and then calculate the temperature difference between the set temperature and the current operating temperature. In step S2, the control device 14 may obtain the set of target control parameters corresponding to the temperature difference according to a pre-stored parameter table, wherein the pre-stored parameter table records correspondence between a plurality of preset temperature intervals and a plurality sets of preset control parameters, and each of the plurality sets of preset control parameters comprises a proportional coefficient, an integral coefficient and a differential coefficient. Specifically, step S2 may include: obtaining the absolute value of the at least one temperature difference, and obtain the target control parameters corresponding to the absolute value according to the pre-stored parameter table. For example, please refer to the following Table (1).

TABLE 1

| Preset temperature | Temperature | Preset control |
|---|---|---|
| interval | difference | parameters |
| I₁ | \|ΔT\| ≤ e1 | [Kₚ₁ Kᵢ₁ K_{d1}] |
| I₂ | e1 < \|ΔT\| ≤ e2 | [Kₚ₂ Kᵢ₂ K_{d2}] |
| I₃ | e2 < \|ΔT\| ≤ e3 | [Kₚ₃ Kᵢ₃ K_{d3}] |
| I₄ | e3 < \|ΔT\| ≤ e4 | [Kₚ₄ Kᵢ₄ K_{d4}] |
| Non-reaction interval | e4 < \|ΔT\| | [Kₚ₅ Kᵢ₅ K_{d5}] |

In Table (1), I₁ to I₄ represent the first to fourth temperature intervals, ΔT is the temperature difference (the set temperature minus the current operating temperature), e1 to e4 are the first to the fourth temperature differences respectively, and among the control parameters, Kₚ is the proportional coefficient, Kᵢ is the integral coefficient, K_{d} is the differential coefficient. After obtaining a set of target control parameters corresponding to the temperature difference according to Table (1), in step S3, the control device 14 may obtain a heat dissipation control parameter using the target control parameters and the at least one temperature difference. Please refer to the following relation (A).

$$u = Kp * e + Ki {\int }_{0}^{t} edt + Kd \frac{de}{dt} \qquad Relation ( A )$$

In relation (A), “u” is the heat dissipation control parameter, “Kₚ” is the proportional coefficient, “Kᵢ” is the integral coefficient, “K_{d}” is the differential coefficient, and “e” is the temperature difference. Specifically, the heat dissipation control parameter may be physical parameters related to heat dissipation efficiency in the liquid-cooling system, such as the rotational speed of the liquid-cooling pump, the flow rate of the liquid-cooling pump, the thermal resistance of the liquid-cooling plate, etc. In step S4, the control device 14 may adjust the rotational speed of the liquid-cooling pump 11 according to the heat dissipation control parameter to complete the adaptive adjustment of the rotational speed or output flow rate of the liquid-cooling pump.

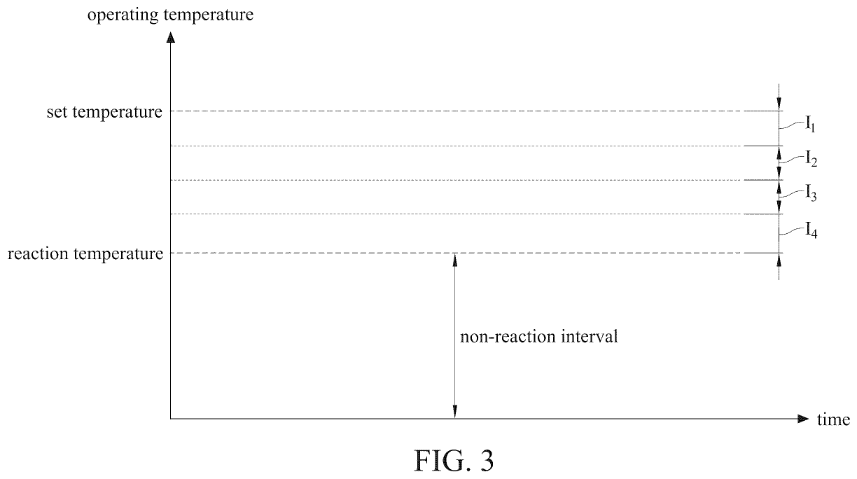

Please refer to FIG. 3 along with Table (1), FIG. 3 shows the relationship between the set temperature, reaction temperature and multiple preset temperature intervals recorded in the pre-stored parameter table in the liquid-cooling dynamic flow control method according to an embodiment of the present disclosure. As shown in FIG. 3, the first to the fourth temperature intervals I₁ to I₄ are corresponding to a plurality of temperature intervals between the set temperature and the reaction temperature, wherein the first temperature interval I₁ is closest to the set temperature and the fourth temperature I₄ is closest to the reaction temperature. It should be noted that the number of the temperature intervals defined between the set temperature and the reaction temperature are not limited to four, and can be decided based on different circumstances for each liquid-cooling system aiming for adaptively adjusting the control parameters with respect to different temperature intervals, thereby smoothing the adjusting process of the rotational speed of the liquid-cooling pump. It can be seen from Table (1) that the relationship between the first to the fourth temperature differences is e1<e2<e3<e4. It should be noted that there is a non-reaction temperature interval defined as the operating temperature lower than the reaction temperature.

Through the pre-stored parameter table (1), the corresponding target control parameters may be determined based on the current operating temperature of the power component, to adaptively adjust the output flow of the liquid-cooling pump. Specifically, in the pre-stored parameter table (1), the plurality of preset temperature intervals may include a non-reaction temperature interval, an upper limit of the non-reaction temperature interval is lower than a reaction temperature, and one set of the preset control parameters which corresponds to the non-reaction temperature interval has the smallest value among the plurality sets of preset control parameters. That is, [Kₚ₅ Kᵢ₅ K_{d5}] in Table (1) may have the smallest value among the plurality sets of preset control parameters. In particular, when the operating temperature of the power component is lower than the reaction temperature, it means that the power component is not yet in a higher loading state at this time. Therefore, the control device may use one of plurality sets of the preset control parameters with the smallest value as the target control parameters, to allow the liquid-cooling pump to run at relative low speed. For example, the reaction temperature may be determined based on the operating temperature of at least one power component in an operating state.

In the preset parameter table (1), in addition to the non-reaction temperature interval, the plurality of preset temperature intervals may include a first temperature interval I1 and a second temperature interval I2, wherein a lower limit of the first temperature interval I1 and a lower limit of the second temperature interval I2 are greater than a reaction temperature, the temperature difference between the first temperature interval I1 and the set temperature is smaller than the temperature difference between the second temperature interval I2 and the set temperature, and at least one value of the second control parameters [Kₚ₂ Kᵢ₂ K_{d2}] corresponding to the second temperature 12 is greater than the at least one value of the first control parameters [Kₚ₁ Kᵢ₁ K_{d1}] corresponding to the first temperature I1. Furthermore, the relationship between the first to the fourth control parameters may be: [Kₚ₄ Kᵢ₄ K_{d4}]> [Kₚ₃ Kᵢ₃ K_{d3}]> [Kₚ₂ Kᵢ₂ K_{d2}]> [Kₚ₁ Kᵢ₁ K_{d1}]. Accordingly, as the temperature of the power component gets closer to the set temperature, the at least one value of the control parameters may become smaller. When the temperature of the power component is in the first temperature interval I1, it may be regarded as reaching an equilibrium state. At this time, the at least one value of the first control parameters may be greater than the at least one value of the fifth control parameters corresponding to the non-reaction interval. That is, [Kₚ₁ Kᵢ₁ K_{d1}]> [Kₚ₅ Kᵢ₅ K_{d5}].

It should be noted that FIG. 3 merely shows the temperature intervals below the set temperature. However, for the temperature intervals above the set temperature, they may be divided according to the temperature difference, as shown in Table (1). For example, the first temperature interval I1 may cover the temperature interval of |ΔT|≤e1 that is above the set temperature, similarly for the second to the fourth temperature intervals I2 to I4.

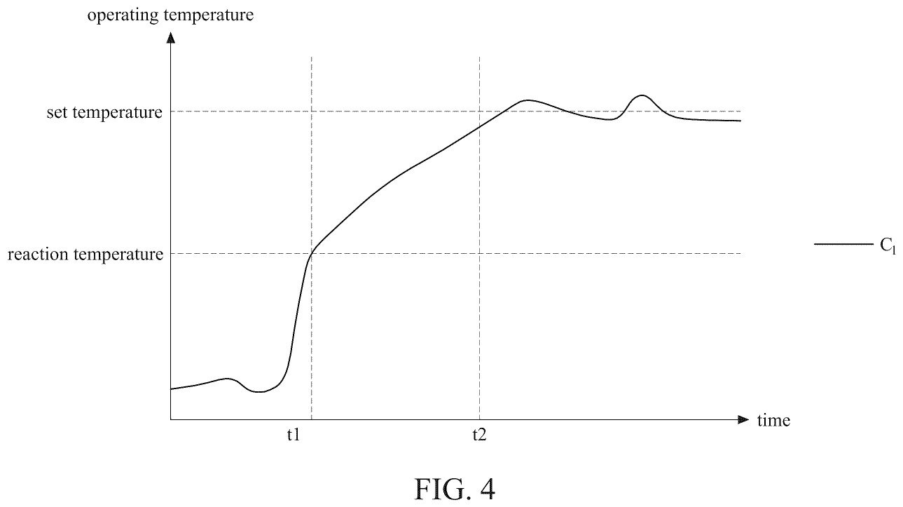

For example, please refer to FIG. 4 which schematically shows the temperature change curve of a power component for heat dissipation using a liquid-cooling dynamic flow control method according to an embodiment of the present disclosure. As shown in FIG. 4, data C1 represents the change in the operating temperature of the power component. Before time point t1, the operating temperature of the power component is lower than the reaction temperature. At this time, the control device may select the fifth control parameters [Kₚ₅ Kᵢ₅ Kas] as the target control parameters according to Table (1). Between time points t1 and t2, the operating temperature of the power component is higher than the reaction temperature. At this time, the control device may sequentially select the fourth to the second control parameters [Kₚ₄ Kᵢ₄ K_{d4}] to [Kₚ₂ Kᵢ₂ K_{d2}] as multiple sets of target control parameters with decreasing values according to Table (1), to adaptively adjust the rotational speed of the liquid-cooling pump. After time point t2, the temperature difference between the operating temperature of the power component and the set temperature is within a threshold range and reaches equilibrium. At this time, the control device may select the first control parameters [Kₚ₁ Kᵢ₁ K_{d1}] as the target control parameters according to Table (1).

In addition, when the rack server contains multiple power components, the liquid-cooling dynamic flow control method in this disclosure may adopt different control schemes for step S2 described above. For example, in one implementation, step S2 may include: obtaining a plurality sets of candidate control parameters corresponding to each of the plurality of temperature differences according to the pre-stored parameter table; and selecting one of the plurality sets of candidate control parameters with the greatest value as the target control parameters. Alternatively, in another implementation, step S2 may include: obtaining the target control parameters corresponding to one of the plurality of temperature differences with the greatest temperature difference according to the pre-stored parameter table. That is, when a rack server contains multiple power components, the control device may first obtain the target control parameters corresponding to each power component, and then select the one with the greatest value as the target control parameters of the liquid-cooling pump; or, the control device may also first obtain the current operating temperatures of each power component, compare the current operating temperatures and then determine the one with the greatest temperature difference in the reaction temperature interval, and determine the target control parameters accordingly.

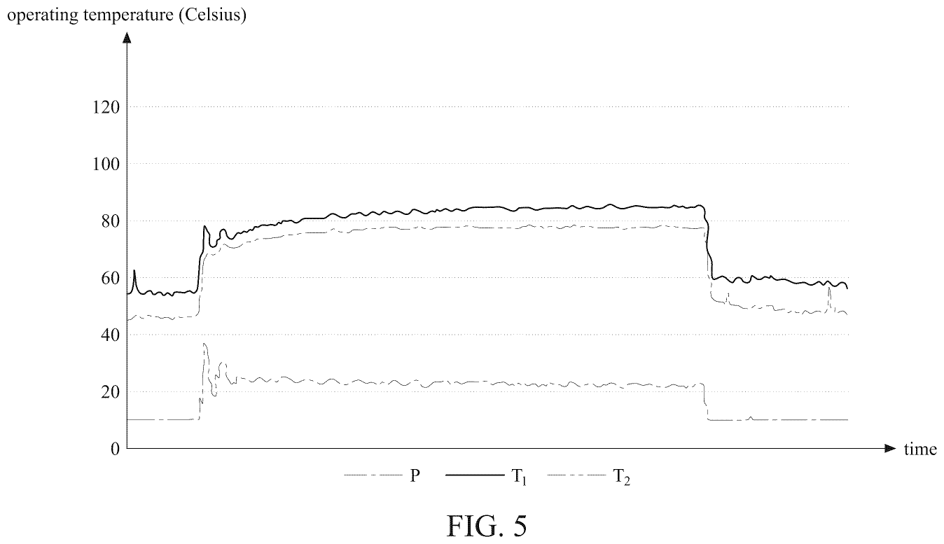

Please refer to FIG. 5 which is a schematic diagram illustrating the relationship between the temperature change of the power component and the rotational speed of the liquid-cooling pump according to an embodiment of the present disclosure. The liquid-cooling system in this embodiment contains two power components. As shown in FIG. 5, data P represents the rotational speed of the liquid-cooling pump, data T₁ represents the operating temperature of the first power component, and data T₂ represents the operating temperature of the second power component. It can be seen that when the operating temperatures of the two power components are low (with less loading), the liquid-cooling pump is controlled to run at a low rotational speed to lower power consumption. As the operating temperature of the two power components increases (the load increases), the liquid-cooling pump is controlled to run at a higher rotational speed to increase the cooling capacity.

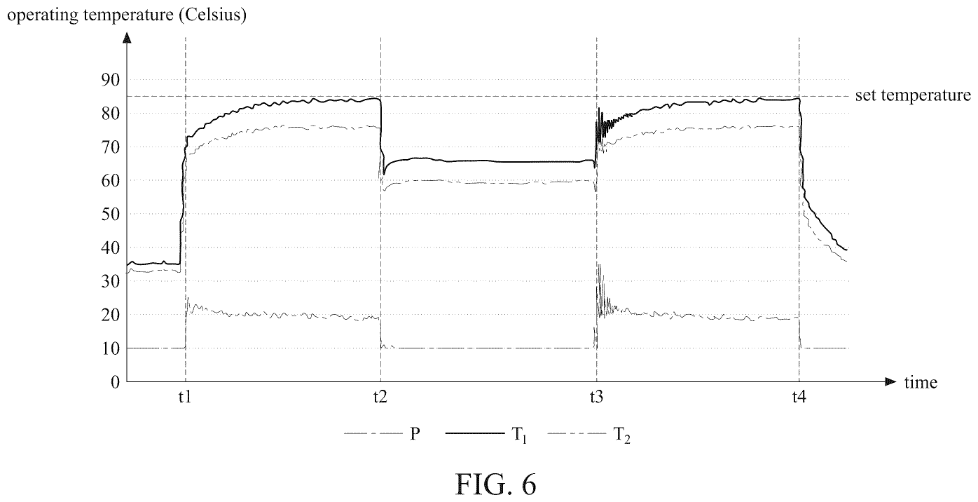

Please refer to FIG. 6 which is another schematic diagram illustrating the relationship between the temperature change of the power component and the rotational speed of the liquid-cooling pump according to an embodiment of the present disclosure. The liquid-cooling system in this embodiment contains two power components. As shown in FIG. 6, data P represents the rotational speed of the liquid-cooling pump, data T₁ represents the operating temperature of the first power component, and data T₂ represents the operating temperature of the second power component. It can be seen that before time point t1 and after time point t4, when the operating temperature of the two power components are 30 to 40 degrees Celsius, the liquid-cooling pump is controlled to run at a low rotational speed to lower power consumption. Between time points t1 and t2 and between time points t3 and t4, when the operating temperature of at least one of the two power components is 70 to 90 degrees Celsius, the liquid-cooling pump is controlled to run at a higher rotational speed. Between time points t2 and t3, when the operating temperature of the two power components are 60 to 70 degrees Celsius, the liquid-cooling pump is still controlled to run at a low rotational speed to lower power consumption.

In this embodiment, the server of the present disclosure may be used for artificial intelligence (AI) computing, edge computing, and may also be used as a 5G server, cloud server or Vehicle-to-everything (V2X) server.

In view of the above description, the liquid-cooling dynamic flow control method and liquid-cooling system of the present disclosure, according to a pre-stored parameter table that records the correspondence a plurality of preset temperature intervals and a plurality sets of preset control parameters, may select the corresponding target control parameters according to which preset temperature interval the current operating temperature of the power component belongs to, thereby dynamically adjusting the rotational speed of a liquid-cooling pump. In this way, the liquid-cooling pump may be prevented from operating in a fully operating state for a long time, and for rack server containing several to dozens of servers, the above dynamic control method may solve the time delay problem in data acquisition caused by the large amount of data and the long acquisition time. In particular, when the temperature of the power component is lower than the reaction temperature, the liquid-cooling dynamic flow control method in this disclosure may use the control parameter with minimum value to control the liquid-cooling output. When the temperature of the power component is higher than the reaction temperature, the value of the control parameter that is used to control the liquid-cooling output may gradually become smaller as the temperature approaches the set temperature. Therefore, the liquid-cooling dynamic flow control method and liquid-cooling system of the present disclosure may achieve dynamic adaptive control and avoid abrupt changes in the rotational speed of the liquid-cooling pump.

What is claimed is:

1. A liquid-cooling dynamic flow control method, controlled by a control device, the liquid-cooling dynamic flow control method comprising:
obtaining at least one temperature difference between a set temperature and at least one current operating temperature of at least one power component;
obtaining a set of target control parameters corresponding to the at least one temperature difference according to a pre-stored parameter table, wherein the pre-stored parameter table records correspondence between a plurality of preset temperature intervals and a plurality sets of preset control parameters, and each of the plurality sets of preset control parameters comprises a proportional coefficient, an integral coefficient and a differential coefficient;
obtaining a heat dissipation control parameter using the set of target control parameters and the at least one temperature difference; and
using the heat dissipation control parameter to adjust rotational speed of a liquid-cooling pump.

2. The liquid-cooling dynamic flow control method of claim 1, wherein in the pre-stored parameter table, the plurality of preset temperature intervals comprise a non-reaction temperature interval, the non-reaction temperature interval is lower than a reaction temperature, and one of the plurality sets of preset control parameters corresponding to the non-reaction temperature interval has a smallest value among the plurality sets of preset control parameters, wherein the reaction temperature is lower than the set temperature.

3. The liquid-cooling dynamic flow control method of claim 1, wherein in the pre-stored parameter table, the plurality of preset temperature intervals comprise a first temperature interval and a second temperature interval, the first temperature interval and the second temperature interval are greater than a reaction temperature, a temperature difference between the first temperature interval and the set temperature is smaller than a temperature difference between the second temperature interval and the set temperature, and at least one value of a set of second control parameters corresponding to the second temperature interval is greater than at least one value of a set of first control parameters corresponding to the second temperature interval, wherein the reaction temperature is lower than the set temperature.

4. The liquid-cooling dynamic flow control method of claim 2, wherein the reaction temperature is determined according to an operating temperature of the at least one power component under a loading state.

5. The liquid-cooling dynamic flow control method of claim 3, wherein the reaction temperature is determined according to an operating temperature of the at least one power component under a loading state.

6. The liquid-cooling dynamic flow control method of claim 1, wherein obtaining the set of target control parameters corresponding to the at least one temperature difference according to the pre-stored parameter table comprises:
obtaining an absolute value of the at least one temperature difference, and obtaining the set of target control parameters corresponding to the absolute value according to the pre-stored parameter table.

7. The liquid-cooling dynamic flow control method of claim 1, wherein the at least one power component comprises a plurality of power components, the at least one temperature difference comprises a plurality of temperature differences, and obtaining the set of target control parameters corresponding to the at least one temperature difference according to the pre-stored parameter table comprises:
obtaining a plurality sets of candidate control parameters respectively corresponding to the plurality of temperature differences according to the pre-stored parameter table; and
selecting one of the plurality sets of candidate control parameters with greatest value as the set of target control parameters.

8. The liquid-cooling dynamic flow control method of claim 1, wherein the at least one power component comprises a plurality of power components, the at least one temperature difference comprises a plurality of temperature differences, and obtaining the set of target control parameters corresponding to the at least one temperature difference according to the pre-stored parameter table comprises:
obtaining the set of target control parameters corresponding to one of the plurality of temperature differences with a greatest temperature difference according to the pre-stored parameter table.

9. A liquid-cooling system, applicable for dissipating heat from at least one power component, the liquid-cooling system comprising:
a liquid-cooling pump configured to set rotational speed according to a heat dissipation control parameter to output coolant;
at least one liquid-cooling plate in thermal contact with the at least one power component and connected to the liquid-cooling pump;
at least one temperature sensor disposed to correspond to the at least one power component, and configured to obtain at least one current operating temperature of the at least one power component; and
a control device connected to the liquid-cooling pump and the at least one temperature sensor, and configured to obtain a set of target control parameters corresponding to at least one temperature difference according to a pre-stored parameter table, obtain a heat dissipation control parameter using the set of target control parameters and the at least one temperature difference, and use the heat dissipation control parameter to adjust rotational speed of the liquid-cooling pump, wherein the pre-stored parameter table records correspondence between a plurality of preset temperature intervals and a plurality sets of preset control parameters, and each of the plurality sets of preset control parameters comprises a proportional coefficient, an integral coefficient and a differential coefficient.

10. The liquid-cooling system of claim 9, wherein in the pre-stored parameter table, the plurality of preset temperature intervals comprise a non-reaction temperature interval, an operating temperature of the at least one power component corresponding to the non-reaction temperature interval is lower than a reaction temperature, and one of the plurality sets of preset control parameters corresponding to the non-reaction temperature interval has a smallest value among the plurality sets of preset control parameters, wherein the reaction temperature is lower than a set temperature.

11. The liquid-cooling system of claim 9, wherein in the pre-stored parameter table, the plurality of preset temperature intervals comprise a reaction temperature interval, an operating temperature of the at least one power component corresponding to the reaction temperature interval is not lower than a reaction temperature, the reaction temperature comprises a first temperature interval and a second temperature interval, a temperature difference between the first temperature interval and a set temperature is smaller than a temperature difference between the second temperature interval and the set temperature, and a value of a set of second control parameters corresponding to the second temperature interval is greater than a value of a set of first control parameters corresponding to the second temperature interval, wherein the reaction temperature is lower than the set temperature.
